(19) United States
(12) Patent Application Publication
(10) Pub. No.: US 2022/0013371 A1
(43) Pub. Date: Jan. 13, 2022

(54) MOLD TOOL FOR MOLDING A SEMICONDUCTOR POWER MODULE WITH TOP-SIDED PIN CONNECTORS AND METHOD OF MANUFACTURING SUCH A SEMICONDUCTOR POWER MODULE

(71) Applicant: Danfoss Silicon Power GmbH, Flensburg (DE)

(72) Inventors: Zeno Müller, Nordborg (DK); Tino Filipiak-Ressel, Nordborg (DK); Holger Beer, Nordborg (DK); Lars Paulsen, Nordborg (DK); Alexander Streibel, Nordborg (DK)

(21) Appl. No.: 17/291,725

(22) PCT Filed: Oct. 24, 2019
(86) PCT No.: PCT/EP2019/079023

§ 371 Date: May 6, 2021

(30) Foreign Application Priority Data
Nov. 7, 2018 (DE) 10 2018 219 003.8
Nov. 7, 2018 (DE) 10 2018 219 005.4

(51) Int. Cl. H01L 21/56; B29C 45/14

(52) U.S. Cl. CPC H01L 21/565; B29L 2031/3481; B29C 45/14639; B29C 45/14418

(57) ABSTRACT

A mold tool 1 is described for molding a semiconductor power module having an electrical contact pin 2 which includes an electrical contact portion 3 for contacting a substrate 4 with another electrical component. The pin 2 comprises a protruding portion 5 being a top-sided pin connector. The mold tool 1 includes a first 6 and a second mold die which, when brought together for molding, form a cavity to be filled with a mold compound for encapsulating electrical components of the semiconductor power module, and a recess 7 in the first die 6 which communicates with the cavity within the second die. The recess 7 is filled with a cushion-like soft material 8 into which the top-sided pin connector is pushed thereinto and completely surrounded by the soft material so that a sealing means is formed that prevents any contamination of the electrical contact portion 3 of the pin 2 by the molding compound introduced into the cavity. Furthermore, a method of manufacturing such a semiconductor power module is described.

### CROSS-REFERENCE TO RELATED APPLICATIONS

This application is a National Stage application of International Patent Application No. PCT/EP2019/079023, filed on Oct. 24, 2019, which claims priority to German Patent Application No. 102018219003.8 filed on Nov. 7, 2018 and German Patent Application No. 102018219005.4 filed on Nov. 7, 2018, each of which is hereby incorporated by reference in its entirety.

### TECHNICAL FIELD

The invention relates to a mold tool for encapsulating a semiconductor power module having top-sided pin connectors as well as a method of manufacturing such a semiconductor power module.

### BACKGROUND

Traditionally, semiconductor power modules being formed by encapsulating the electronics have input and output leads which exit the molded module at the intersection of the two parts of the mold used for forming the encapsulation. This restricts the placements of leads to a plane substantially around the module. For reasons of increasing compactness and creepage distances between adjacent leads, it is disadvantageous to restrict placement of leads just in one plane so that the number of leads is rather restricted that can be arranged for one module. This is contrary to increasing the compactness of such modules. It is known in the art that an external contact on the top of a power module that means to create top-sided contact pins is difficult to mold because there are extreme difficulties to create a seal at the point of exit which influence leaking of mold compound during the molding process. It has to be borne in mind that top-sided contact pins should never be spoiled or contaminated by mold compound during the molding for encapsulating the electronics. One prior art approach is to simply create a metallic surface in plane with the mold surface onto which the contact pins are connected by drilling, welding, gluing, sintering or otherwise after the molding process is complete. However, this is disadvantageous just because it requires an extra manufacturing step.

### SUMMARY

Therefore, it is the object of the present invention to provide a semiconductor power module formed by encapsulating the electronics and yet leaving top-sided contact pins which can be kept completely clean from the mold compound during molding so that they can provide for a good electric conductivity when connected to other electronic components. A further object is to provide a method of manufacturing such a semiconductor power module having top-sided contact pins which are free of any mold compound even after molding has been completed so that excellent electric conductivity can be provided when the electrical connecting pins are connected to other electronic components.

This object is solved by a mold tool for molding a semiconductor power module with an electrical contact pin is provided which comprises an electrical contact portion for contacting a substrate and a protruding portion being a top-sided pin connector. The mold tool comprises a first and a second mold die which, when brought together for the molding process, form a cavity to be filled with a mold compound. After the mold compound has cured, the electrical components of the semiconductor power module are encapsulated. The first, upper die comprises a recess communicating with the cavity which is being part of the second, lower die. According to the invention, the recess is filled with a cushion-like soft material into which the top-sided pin connector is pushed so as to be completely surrounded by the soft material and to form a sealing device. As the top-sided pin connector is surrounded by the cushion-like soft material and preferably its viscosity is such that compound material being filled, injected or even pressed into the cavity of the lower die the cushion-like soft material stays in place and protects the top-sided pin connector. That means, the cushion-like soft material prevents the mold compound from reaching the electrical contact region of the top-sided pin connector. That means that the cushion-like soft material prevents contamination of the electrical contact portion of the pin connector by the mold compound which is introduced into the cavity. To that extent the cushion-like soft material forms a sealing means.

By means of this cushion-like soft material as the sealing means, the general challenge can be met to avoid any contamination of the contact area of the pins by the mold compound. Generally, such pins might be simple soldered pins, pins of a particular form such as press-fit pins which are meant for insertion into holes in PCBs or pins with holes or threaded holes formed therein for using screw connections. The cushion-like soft material may comprise a natural material such as rubber or a synthetic material such a silicone or a polytetrafluoroethylene (PTFE)-based material. Whatsoever materials are being used, the material should be able to withstand temperatures and pressures used in the molding process. For example, preferably a temperature range of 160° to 220° or even higher and pressures of at least 10 MPa should be easily coped with by the soft material. The soft material is integrated into the recess of the first mold die that means the upper die of the mold tool. The consistency of this soft material should be such that even under the pressure in the cavity when the mold compound is being injected or even pressed into the cavity of the lower die of the mold tool, it should not be compressed or pressed out of the recess, not even under a condition where the electrical contact portion of the electrical contact pin is taken up inside the soft material and completely covered so as to prevent any mold compound from reaching this electrical contact portion of the pin and therefore, any kind of contamination of the contact area of the pin by the mold compound is avoided. The soft material that means the cushion-like soft material should be able to withstand several thousand production cycles before having to be replaced. A mold tool that is used for molding a semiconductor power module with top-sided pin connectors as well as the inventive method of manufacturing a semiconductor power module comprising such top-sided pin connectors have the following advantages: It allows a much greater freedom of placement of contacts, so that increase of compactness is no longer an issue.

It allows contacts to be much more spread-out around the surface of the module and this is often a great advantage because there is a much greater freedom of placement of contacts, let alone the number of contacts which can be increased around the outer surface of the encapsulated electronics, that means the module. The spreading around the surface of the top-sided pin connectors can be used even if there are high-voltages applied between the contacts and in doing so, the distances required to avoid sparking can be maintained despite an increase of the number of pins for the module. So, the corresponding top contact layout enables a reduction of stray inductance which is increasingly significant for new technologies such as the use of silicon carbide semiconductors which allow higher and higher switching speeds. In the context of this application, top-sided contact pins mean that these pins protrude from any surface of the module other than the plane corresponding to the interface plane of the upper die and the lower die of the mold tool. Because of the fact that the top contacts can go straight down to the circuit board, that is, the substrate of the module, space may be saved on the substrate because there is no need for conductors along the surface of the circuit board. This allows circuit boards to become smaller and smaller by means of which the overall size of the module can be reduced. And furthermore, the top contacts allow for shorter control signal paths. Apart therefrom, the top contacts make the design of symmetric control signal paths to the various switching semiconductors much easier. Therefore, the simultaneous control of multiple semiconductors in parallel can be implemented much easier as compared to other layouts.

According to a further embodiment, the recess of the upper die of the mold tool is preferably drilled or machined into the bottom that means from the bottom side of the first die and having a size to take up the complete electrical contact portion of the electrical contact pin. The recess may also be designed such that it broadens out further from the cavity of the lower die towards the upper side, that means from the intersection line of the lower die and the upper die into the upper die in order for the soft material to retain in position within the recess of the upper mold die. For some soft materials, it may be an advantage to increase the pressure within the material simultaneously with transferring mold compound into the mold cavity. This may be done by an external pressurizing device which communicates with the soft material recess through a passage in the wall of the mold. Alternatively, this might be achieved by a careful shaping of the upper portion of the pin itself. For example, the pin can be provided with an area of increased diameter as compared to the upper most portion of the pin which represents the actual contact portion of the pin so that this area of the pin comprises a collar-like shoulder or an area of increased diameter that is pushed slightly into the mold material when the mold is closed and act as a kind of piston to increase the pressure within the soft material to even more guaranteeing a complete coverage of the soft material around the outer surface of the frontmost portion of the pin. Such a pressurizing passage guarantees that the soft material stays in the recess and fulfills its function of preventing mold compound from reaching the contact portion of the pin.

Preferably, the module comprises several pins which are held together by an integral unit of the sealing means. In order to refine the exact force used for inserting the pin into the soft material into the recess of the upper die, the actual length of the pin will have to be chosen carefully. Alternatively, some form of a kind of a spring may be built into the structure of the pin itself which will limit the force applied by the pin to the soft material as it is inserted. This spring-kind of structure can be a relief portion having elastically bendable portions which guarantee a deformation rather than a deformation of the shaft of the pin itself.

According to a second aspect of the invention, a method of manufacturing a semiconductor power module having top-sided contact pins is described. The inventive method comprises the steps of:
a) supplying a subassembly comprising a first mold die with a recess which is at least partially filled with soft material and which faces to a mold cavity within the second mold die and arranged around a substrate to be encapsulated by a mold compound, the first and the second mold die forming a mold tool;
b) placing a substrate into the cavity of the second mold die and the pin being fixedly held by a sealing device and placed onto the substrate;
c) closing the first and the second mold die together so that the electrical contact portion of the pin is inserted into the soft material within the recess; and
d) transferring mold compound into the cavity of the mold tool.

These steps guarantee that the electronics can be encapsulated by the mold material because the electronics arranged on a substrate or stacked together with a substrate is set into the cavity where the mold compound is filled in and cures so that the electronics is finally encapsulated. The length of the contact pins is designed such that it protrudes outside the lower die with the height which can be taken up in the recess arranged in the upper die filled with the soft material so that the protruding portion of the pin penetrates into the soft material is completely covered by this material. Thus, the soft material acts as a sealing means which prevents mold compound from flowing into the recess so that after taking out the encapsulated module out of the module tool, the top-sided pins are completely free of any contamination from mold compound and can be directly used for an electrical connection to any other electrical component.

Preferably, the electrical contact portion of the pin is sealed for preventing mold compound from coming into contact with the electrical contact region. This is realized by the electrical insulating surface being arranged perpendicular to the direction of movement of the first and the second die for closing the mold tool for the molding process.

At last, the electrical contact portion of the pin is inserted into the recess at closed mold tool after the recess has been filled with the cushion-like soft material.

A semiconductor power module with top-sided contact pins manufactured according to the described method provides for an encapsulated module with contact portions of pins protruding from the surface of the encapsulated module which are not contaminated by the mold compound used for encapsulating the electronics.

Further details and a general understanding of the invention will become clear with the embodiment described in the drawings for two states, the first one with the top-sided contact pin not yet inserted into the recess of the first, upper die and the second drawing with the top-sided pin contact being completely inserted into the soft material within the upper die, as a matter of course with only the front portion of the pin being penetrated into the soft material within the recess of the upper die.

### BRIEF DESCRIPTION OF THE DRAWINGS

FIG. 1 shows an electrical component of a semiconductor power module with an electrical contact pin fixed to a substrate prior to being inserted into a recess of a first die of a mold tool; and

FIG. 2 shows the electrical component of the semiconductor power module with the electrical contact pin according to FIG. 1, however, being inserted into the recess of the first die filled with the cushion-like soft material.

FIG. 3 shows a partial sectional view of the first mold die with the recess in a dovetail shape and a protective film as well as a pressurizing passage connected to the recess.

FIG. 4 a side view of a subassembly of several pins combined in one integral insert unit arranged on a substrate fixed on a base plate;

FIG. 5 a three-dimensional view of an arrangement according to FIG. 4;

FIG. 6 a three-dimensional view of an arrangement according to FIG. 4 or FIG. 5, after encapsulation by a molded casing arranged on the base plate with electrical contact portions of the pins extending from the molded casing;

FIG. 7a a subassembly arrangement according to FIG. 4 with a first mold die on top of the assembly, however, not yet lowered down for a molding process;

FIG. 7b the arrangement according to FIG. 7a, however, with the first mold die lowered down with the edges of its recess to seal off the recess from a cavity into which mold compound is to be injected or inserted;

FIG. 8 represents the foot region of a pin comprising a relief section and being mounted on a substrate;

FIG. 9 a representation of a pin being mounted on a substrate and being about to be inserted into a recess in the first mold die filled with a cushion-like soft material; and

FIG. 10 shows a flow diagram of the major method steps for manufacturing an inventive semiconductor power module.

### DETAILED DESCRIPTION

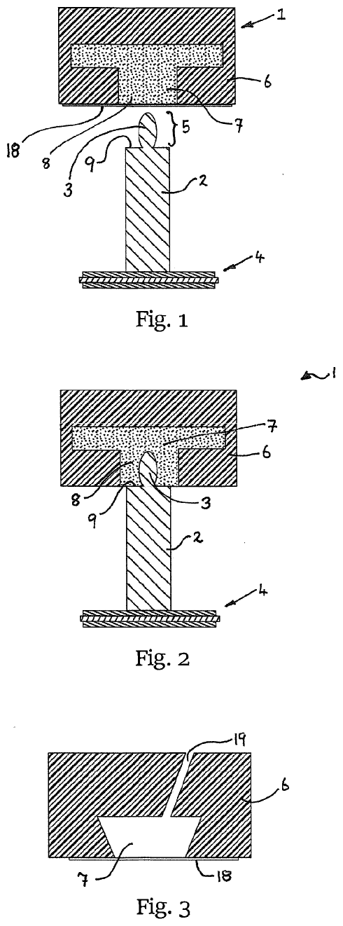

FIG. 1 represents a semiconductor power module which is represented just as a principal component being a DCB (direct bonded copper) substrate 4 onto the upper surface of the substrate for an electrical contact pin 2 to be fixed thereto to electrically connect the pin to the substrate. The electrical contact pin 2 extends from the surface of the substrate 4 perpendicularly and is ready to be inserted into a recess 7 within a first die 6 being an upper die of a mold tool 1. The second die, being a lower die (not shown), is for encapsulating the electrical component by injecting a mold compound into the cavity of the lower die.

The recess 7 within the first, upper mold die 6 is filled with a cushion-like soft material 8, the consistency of which, that means its viscosity, is such that it is displaceable when the electrical contact portion 3 is being inserted into this soft material 8 within the recess 7 of the upper mold die 6 of the mold tool 1. The viscosity of the soft material 8 is high enough that it is kept within the recess 7 that means it does not flow out from this recess 7, though soft enough for a protruding portion 5 as the electrical contact portion 3 to penetrate thereinto, displacing it and arranging for the electrical contact portion 3 to be completely surrounded by the soft material 8. By the term “completely surrounded” it is to be understood that the soft material 8 protects the entire surface of the electrical contact portion from the mold compound when the latter one is being inserted into the cavity of the second mold die of the mold tool 1. The soft material is not only displaceable by the electrical contact portion 3 which represents a protruding portion 5 of the pin 2, it is also, at least to a certain extent, compressible in order to further improve the sealing function of the soft material 8. In general, by encircling the complete surface of the protruding portion 5 of the electrical contact pin 2, a sealing means preventing mold compound being injected into the cavity of the lower die from contaminating the electrically conducting surface of the electrical contact portion 3.

In addition thereto, the electrical contact pin 2 comprises at its protruding portion 5 a collar-like section 9 which is designed in the shape of a shoulder and which acts as a piston-like surface when the protruding portion 5 is being inserted or pressed into the soft material 8 in the recess 7 of the upper die 6 of the mold tool 1. This kind of compression of the soft material increases the sealing function of the soft material 8 for the electrical contact portion 3 of the pin 2.

A protective film 18 may be arranged on the bottom side of the first mold die preferably completely extending over the opening of the recess 7 for receiving the contact pin 2. This protective film 18 is designed such that when the contact portion 5 of the pin 2 penetrates into the soft material 8 the protective film 18 engages the entire outer surface of the contact pin so as to prevent any soft material from directly engaging the surface of the electrical contact portion 5. The protective film 18 comprises the property of not adhesively sticking to the surface of the contact portion 5 and yet preventing any direct contact of the soft material 8 with the surface of the electrical contact portion 5 of the pin 2.

Whilst FIG. 1 represents the state of the pin 2 just about to be inserted into the soft material 8 within the recess 7 of the upper die 6, FIG. 2 represents the state where the protruding portion 5 of the pin 2 has been completely inserted into the cushion-like soft material 8 within the recess 7 of the upper die 6 of the mold tool 1. It can be seen from FIG. 2 that the collar-like section 9, that means the shoulder, in the range of the protruding portion 5 of the pin 2 is at least approximately flush with the lower side surface of the upper mold die 6 so that the vast majority of the opening area of the recess 7 is covered by this collar-like section 9 and that a range or an amount of the soft material 8, being big enough, is compressed by the collar-like section 9 of the pin 2 so that the sealing function of the soft material 8 is even increased.

In the state as represented in FIG. 2, when the upper mold die 6 has been lowered so that the electrical contact portion 3 of the pin 2 is being inserted into the soft material 8 the lower die, for the sake of simplicity, not represented here, already surrounds the semiconductor power module with the DCB substrate and the pin 2 electrically connected to the electrically connecting surface of the substrate 4 so that the cavity is closed by the internal surface of the cavity of the lower mold die and by the lower surface of the upper die 6 facing towards the lower die. When the two halves of the mold tool, that is the upper die and lower die, have been completely moved towards each other and the intersecting surface between these two dies has been engaged and held together by a certain amount of compression force, the cavity can be injected to by a mold compound completely filling and encapsulating after its curing the electrical component.

It is important to state that the soft material 8 is made of a synthetic silicone and for this embodiment the protruding portion 5 that means the electrical contact portion 3 of the pin 2 is designed as a press fit pin. As a matter of course the shape and design of the pin 2 can also be different, that means not necessarily be a press fit pin. It is to be understood that the viscosity of the soft material 8 may vary also dependent on the shape of the protruding portion 5 of the pin 2 to be inserted into the soft material 8. When the pin 2 is embedded in the soft material 8, which represents the sealing material, it is prevented from so-called being over molded. The basic advantage of this mold tool 1 as well as the method for making such an electrical component having a protruding portion 5 of the pin 2 which is being electrically clean and need not be cleaned once the molding process for the electrical component to be encapsulated by this molding compound has been completed. It is the soft material 8 that with its sealing function prevents the pin from any contamination by the mold compound. It is not only the viscosity of the soft material that counts, it is also the property to withstand a transfer pressure which is at least 10 MPa and also high temperatures of at least 180° C.

FIG. 3 shows a specific detail for the recess 7 formed within the first mold die 6. The recess 7 has a cross sectional shape of a dovetail so as to prevent the cushion-like soft material 8 from easily flowing out of the recess 7. The recess 7 is connected with an optional pressurizing pas-sage 19 through which soft material is supplied under a pressure to increase the internal pressure within the recess 7. At the outside of the recess 7 that means at its opening towards the cavity 16 for molding a protective film 18 is arranged. When the electrical contact portion 5 of the pin 2 is inserted into the recess 7 this protective film 18 covers the surface of the electrical contact portion 5 of the pin 2 completely and prevents any direct contact of the soft material 8 with the surface of the electrical contact portion 5. This also guarantees a completely clean surface of the electrical contact portion 5 after the molding process has taken place so that for any connection of the electrical contact portions 5 of the pins 2 with other electrical components an excellent electrical contact is possible without the addition of a cleaning step for the electrical contact portion 5 which otherwise would be necessary.

In some embodiments, the module being manufactured may comprises several pins which are held together by an integral unit 14. In order to refine the exact force used for inserting the pin into the soft material 8 into the recess of the first mold die6 , the actual length of the pin will have to be chosen carefully. Alternatively, some form of a kind of a spring may be built into the structure of the pin itself which will limit the force applied by the pin to the soft material 8 as it is inserted. This spring-kind of structure can be a relief portion having elastically bendable portions 105 which guarantee a deformation rather than a deformation of the shaft of the pin itself.

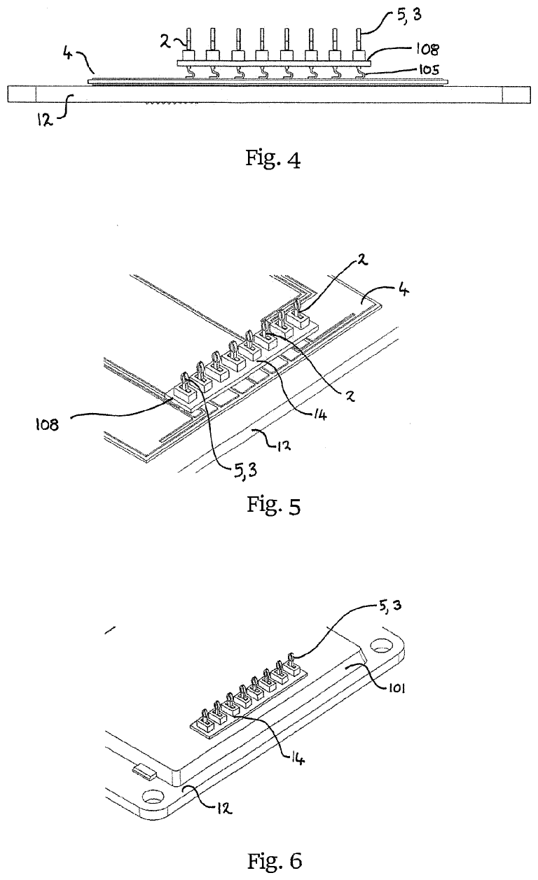

FIG. 4 shows a side view of the integral unit 14 which comprises several pins to be fixedly hold within one integral insert unit by means of which all the pins are properly held and directed so that during molding process their position remains fixed as held in the integral insert unit and within the cavity. The integral insert unit comprises a collar-like portion each, from which an electrical contact portion of the pin extends, the foremost portion which is meant for the electrical contact is formed as a press fit contact portion of the pin 2. The electrical contact portion 5 being shaped as press fit electrical contact portion 3 extends from a holding body of the integral insert unit 14, that is integrally connected with an electrical insulating surface acting as a sealing device 8. The lower portion of the pin extends from underneath the electrical insulating surface of the integral insert unit 14 with its feet to a substrate 4 onto which the feet of the pins are electrically connected to. The feet of the pins comprise a relief portion which is able to take up forces exerted by pressing the first mold die, that means the first mold die 6, onto the electrical insulating surface 108 to form a sealing device and to seal off a recess (not represented in FIG. 4) within the first mold die 6, although not represented in this Figure. The feet of the pin itself can be sufficiently elastic to form a relief portion 105 by the ordinary pin shape as well. The substrate 4 itself is mounted onto a base plate 12 so that the integral unit according to FIG. 4 arranged on the substrate 4 which in turn is fixed to the base plate 12 is ready for the molding process to manufacture a molded semiconductor power module.

FIG. 5 shows the arrangement of FIG. 4, however, in a perspective view. The integral unit 14 holds eight electrical contact pins 2 at the desired position and direction. The electrical contact portion 5, 3 of the pins extend upwards from the integral insert unit 14. The feet of the pins 2 which cannot be seen in this representation, rest upon a substrate 4 comprising printed circuit board tracks. This substrate 4 is connected to a base plate 12 forming the electrical component structure to be molded.

FIG. 6 represents a molded semiconductor power module structure with have the sub-assembly in the form of the integral insert 14 molded into a molded casing together with the feet of the pins as well as the substrate 4. This entire component is fixedly assembled onto the base plate 12.

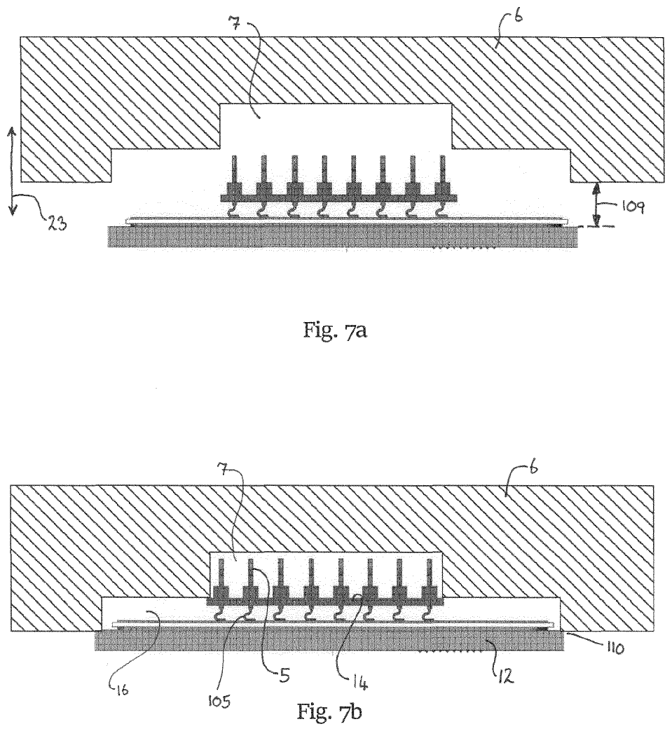

FIG. 7 shows two states of the integral unit together with the first mold die in a first state where the first mold die is just above the integral unit and just about to be moved down onto the integral unit (FIG. 7a)) and in a second state where the first mold die 6 has been moved down onto the integral insert unit 14 with the edge region of a recess 7 formed within the first mold die 6 (FIG. 7b)). It can be seen from FIG. 7a) that the first mold die 6 comprises the recess 7 which is to receive the electrical contact portions 5 of the electrical contacts pins 2 extending upwards from the integral insert unit 14. The first mold die 6 further comprises a cavity 16 which is meant to receive mold compound for encapsulating the electrical component into a molded casing (not represented here). The first mold die 6 is moved in the direction 23 of movement of this first mold die. The height by which the first mold die 6 is to be moved towards the integral unit is as large as to reach from its open position 109 to its closed position 110. When the closed position 110 has been reached the first mold die 6 is pressed with the edges of the recess 7 onto the electrical insulating surface 108 so as to form a sealing device. This sealing device prevents mold compound, injected or inserted into the cavity 16 for molding the integral insert unit 14 into the molded casing to form a molded semiconductor power module (not represented here), from reaching the electrical contact portions 5 of the pins 2 With a force sufficiently high exerted by the first mold die 6 onto the electrical insulating surface 108 a mold compound tight seal will be achieved. With a tight seal no mold compound will ingress into the recess 7 and thus the electrical contact portions 5 of the pins 2 will not be covered or contaminated with mold compound. When the first mold die 6 is pressed onto the electrical insulating surface 108 to form the sealing device, a force F, by means of which the first mold die 6 is pressed onto this electrical insulating surface 108, is exerted onto the feet of the pin 2 and in particular received by the relief portion 105. The force F exerted by the first mold die 6 onto the electrical insulating surface 108 is as high as to reach the upper surface of the base plate 12 with the edges around the cavity 16 also formed within the upper mold die 6. As a matter of course, it is also possible that the cavity 16 is formed by a second mold die, also referred to as lower mold die. Furthermore, it is also possible that the cavity 16 is partially formed within the first mold die 6 and partially within the second mold die, that means the lower mold die (not represented here).

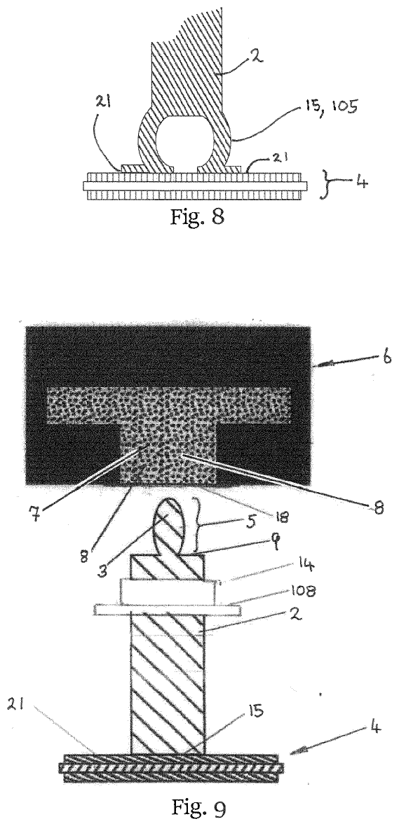

In FIG. 8 a partial detail of the foot region of a contact pin 2 is represented showing a relief portion 105 which is arranged at the substrate-contact portion of the pin 15. The substrate-contact portion 15 is the lower portion of the pin 2, that means the foot portion by means of which the pin 2 is electrically connected to the substrate 4 to form an electrical connection between the electrical contact pin 2 and the pcb tracks on the substrate 4. FIG. 8 shows that the relief portion 105 has taken up some force by the first mold die so that the spring-like relief portion 105 is elastically deformed. Reference numeral 21 indicates the upper surface of the substrate 4 on which the pcb tracks are formed.

FIG. 9 shows another embodiment according to the present invention for a modified sealing device. Again, the electrical contact pin 2 mounted with the substrate-contact portion 15 onto a surface 21 for contacting the substrate 4. The electrical contact pin 2 comprises an integral insert unit 14 having a holding portion to fixedly hold and direct the pin 2 prior to the molding process and an electrical insulating surface 108 which, once the front portion of the electrical contact pin 2 is received within the recess 7 of the first mold die 6, is to completely cover the opening of the recess so that its edges form the sealing device when the first mold die is in its closed position 110. The recess 7 is filled with the cushion-like soft material 8 which is viscous enough not to flow out of the recess 7 and elastically enough to receive the electrical contact portion 5 which is formed as a press-fit electrical contact portion 3 without flowing out of the recess. The electrical contact portion 5 protrudes from a piston-like shoulder 9. As the electrical contact portion 5 and the shoulder 9 are inserted into the cushion-like soft material 8 within the recess, the shoulder 9 acts like a piston and compresses the soft material so that the press-fit electrical contact portion 3 is completely surrounded by the soft material. The first mold die 6 will be moved down as long as the edge portions of the recess 7 facing towards the pin 2 have contacted the electrical insulating surface 108 to form a sealing device. That means, for this embodiment, the sealing device consists of both the electrical insulating surface 108 and the cushion-like soft material 8. A protective film 18 may be arranged on the bottom side of the first mold die preferably completely extending over the opening of the recess 7 for receiving the contact pin 2. This protective film 18 is designed such that when the contact portion 5 of the pin 2 penetrates into the soft material 8 the protective film 18 engages the entire outer surface of the contact pin so as to prevent any soft material from directly engaging the surface of the electrical contact portion 5. The protective film 18 comprises the property of not adhesively sticking to the surface of the contact portion 5 and yet preventing any direct contact of the soft material 8 with the surface of the electrical contact portion 5 of the pin 2.

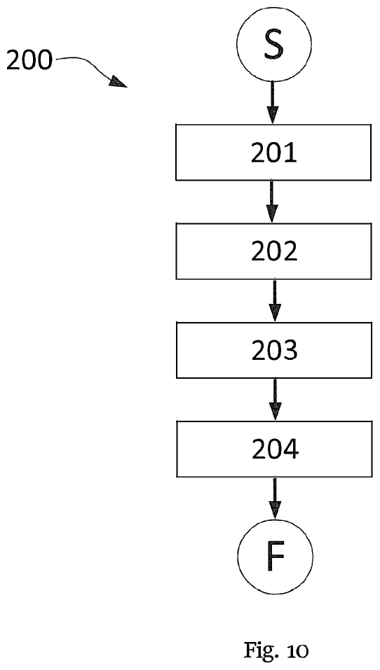

In FIG. 10, the basic sequence 200 of steps is shown for a method of manufacturing a semiconductor power module according to the invention to be carried out.

After the start for carrying out the steps at the point S in the first step 201 a subassembly is supplied that comprises a first mold die 6 and has a recess 7 which is at least partially filled with soft material 8 and which faces to a mold cavity 16 within the second mold die and arranged around a substrate 4 to be encapsulated by a mold compound, the first and the second mold die forming a mold tool.

This first step 201 is followed by the second step 202 for carrying out this inventive method by placing a substrate into the cavity 16 of the second mold die and the pin being fixedly held by a sealing device and placed onto the substrate 4.

In the third step 203 the first 6 and second mold dies are closed together so that the electrical contact portion of the pin is inserted into the soft material 8 within the recess 7.

In the fourth step 204 mold compound is transferred into the cavity 16 of the mold tool. This can be done by simply pressing it thereinto or for example by injection molding. This depends upon the material used for the molding process or the encapsulation required for the module or from other factors known to the persons skilled in the art. After the complete mold of the mold compound has been inserted into the cavity 16, the process of manufacturing the semiconductor power module with an encapsulated casing has been completed.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A mold tool for molding a semiconductor power module with an electrical contact pin comprising an electrical contact portion for contacting a substrate and a protruding portion being a top-sided pin connector, the mold tool comprising a first and a second mold die, which, when brought together for molding, form a cavity to be filled with a mold compound encapsulating electrical components of the semiconductor power module, and a recess in the first die communicating with the cavity, the recess being filled with a cushion-like soft material wherein the top-sided pin connector is pushed thereinto and completely surrounded by the soft material to form a sealing means so as to prevent contamination of the electrical contact portion of the electrical contact pin by the mold compound introduced into the cavity.

2. The mold tool according to claim 1, wherein the soft material is heat-resistant to at least 160 to 220° C. and pressure-resistant to at least 10 MPa and has a viscosity such as to be displaceable when the electrical contact portion of the pin is pushed thereinto.

3. The mold tool according to claim 1, wherein the dies are arranged such that the electrical contact pin of the top-sided pin connector is received within the soft material.

4. The mold tool according to claim 1, wherein the soft material comprises an additional protective film for preventing contamination of the electrical contact portion by the soft material, the soft material pressing the protective film onto the electrical contact portion of the pin when the pin is pushed into the soft material.

5. The mold tool according to claim 1, wherein the recess is a drilled or machined recess arranged in the bottom of the first die having a size to take up the complete electrical contact portion of the pin.

6. The mold tool according to claim 1, wherein the recess widens from the cavity towards an upper side of the first die so as to retain sufficient soft material for taking up the complete electrical contact portion of the pin.

7. The mold tool according to claim 1, comprising a pressurizing passage in a wall communicating with a soft material recess and pressurizing the soft material within the recess.

8. The mold tool according to claim 1, wherein the recess is dimensioned such that a collar-like section of the sealing means arranged for the pin to act as a piston to pressurize the soft material when the first and the second mold die are closed together so that the electrical contact portion of the pin penetrates into the soft material.

9. The mold tool according to claim 1, wherein several pins are held together by an integral unit of the sealing means and are arranged next to each other.

10. A method of manufacturing a semiconductor power module comprising the steps of
a) supplying a subassembly according to claim 1, comprising a first mold die having a recess at least partially filled with soft material and facing to a mold cavity within a second mold die and arranged around a substrate to be encapsulated by a mold compound, the first and the second mold die forming a mold tool;
b) placing the substrate into the cavity of the second mold die and the pin being fixedly held by a sealing means and placed onto the substrate;
c) closing the first and the second mold die together so that the electrical contact portion of the pin is inserted into the soft material within the recess; and
d) transferring mold compound into the cavity of the mold tool.

11. The method according to claim 10, wherein the electrical contact portion of the pin is sealed for preventing mold compound from coming into contact with the electrical contact portion, an electrical insulating surface being arranged perpendicular to the direction of movement of the first and the second die for closing the mold tool.

12. The method according to claim 10, wherein the electrical contact portion of the pin is inserted into the recess at closed mold tool.

13. A semiconductor power module manufactured using the method as claimed in claim 10.

14. The mold tool according to claim 2, wherein the dies are arranged such that the electrical contact pin of the top-sided pin connector is received within the soft material.

15. The mold tool according to claim 2, wherein the soft material comprises an additional protective film for preventing contamination of the electrical contact portion by the soft material, the soft material pressing the protective film onto the electrical contact portion of the pin when the pin is pushed into the soft material.

16. The mold tool according to claim 3, wherein the soft material comprises an additional protective film for preventing contamination of the electrical contact portion by the soft material, the soft material pressing the protective film onto the electrical contact portion of the pin when the pin is pushed into the soft material.

17. The mold tool according to claim 2, wherein the recess is a drilled or machined recess arranged in the bottom of the first die having a size to take up the complete electrical contact portion of the pin.

18. The mold tool according to claim 3, wherein the recess is a drilled or machined recess arranged in the bottom of the first die having a size to take up the complete electrical contact portion of the pin.

19. The mold tool according to claim 4, wherein the recess is a drilled or machined recess arranged in the bottom of the first die having a size to take up the complete electrical contact portion of the pin.

20. The mold tool according to claim 2, wherein the recess widens from the cavity towards an upper side of the first die so as to retain sufficient soft material for taking up the complete electrical contact portion of the pin.
